(19) United States
(12) Patent Application Publication
(10) Pub. No.: US 2009/0316356 A1
(43) Pub. Date: Dec. 24, 2009

(54) ENCLOSURE OF ELECTRONIC DEVICE

(76) Inventor: HSIUNG FEI LU, Wu Ku Hsiang (TW)

Correspondence Address: LEONG C LEI, PMB # 1008, 1867 YGNACIO VALLEY ROAD, WALNUT CREEK, CA, 94598, US

(21) Appl. No.: 12/141,928

(22) Filed: Jun. 19, 2008

(51) Int. Cl. H05K 7/20; H05K 7/02

(52) U.S. Cl. 361/688; 361/809

(57) ABSTRACT

An enclosure is provided for an electronic device, including a single-sheet metal enclosure, which has a frame-like board arranged at a central portion thereof. The frame-like board forms a central opening. The frame-like board has opposite edges, which are bent downward and further extend outward to form parallel side wings, in which fastening holes are defined. The side wings and the frame-like board together form an accommodation space on an underside of the frame-like board. A plurality of fastening elements is respectively fit through the side wings of the enclosure and is secured to a circuit board to have the enclosure securely fit on an electronic device.

### BACKGROUND OF THE INVENTION

(a) Technical Field of the Invention

The present invention relates to an enclosure of an electronic device, and in particular to a metal enclosure for fitting over an electric connector and mountable to a circuit board by means of fastening elements.

(b) Description of the Prior Art

A socket connector is a must for connecting an electronic chip and one side of the electric connector is often soldered to a circuit board. In order to protect solder balls that are to be soldered to the circuit board from detached by being acted upon by external forces, the electric connector is often provided with a metal casing or enclosure that is fit outside the electric connector.

The present invention is made in view of the drawbacks of the conventional, metal-made casing. The conventional metal casing or enclosure comprises a base having a central portion to which a socket connector is bonded and also having an edge to which a metal lid is pivotally connected and an opposite edge to which an operation arm is coupled, whereby when an electronic chip is fit to the electric connector and the lid is closed, the operation arm is actuated to secure the electric connector so ensuring tight engagement between the electronic chip and the electric connector. The conventional metal-made enclosure has to have a dedicate design and often suffers the following disadvantages:

(1) The base and the lid, together with the operation, are of a substantial weight, which makes the positioning in soldering operation very difficult. Further, the amount of metal material for the enclosure is great, leading to a great cost for the materials. This is the primary disadvantage of the conventional enclosure.

(2) The electrical connector has a plastic housing that is directly bonded to the base of the enclosure and such a bonding operation is time-consuming and is a high-temperature process that often causes damage to the parts/components. This is another advantage of the conventional enclosure.

(3) Since the plastic housing of the electric connector is directly bonded to the base of the enclosure, once the electric connector is broken, the whole metal enclosure has to be completely disposed of, making it not possible to repeatedly use the enclosure. This is a further disadvantage of the conventional enclosure.

### SUMMARY OF THE INVENTION

The primary purpose of the present invention is to provide a single thin-metal-sheet enclosure, which works with fastening elements, to securely fasten an electronic device, such as an electric connector, to a circuit board so as to realize easy fastening and reduction of material consumption and saving of costs.

To achieve the above objective, the present invention provides the following solution: a single-sheet metal enclosure is provided, which comprises a frame-like board at a central portion thereof and the frame-like board forms a central opening. The frame-like board has opposite edges, which are bent downward and further extend outward to form parallel side wings, in which fastening holes are defined. The side wings and the frame-like board together form an accommodation space on an underside of the frame-like board. A plurality of fastening elements is respectively fit through the side wings of the enclosure and is secured to a circuit board to have the enclosure securely fit on an electronic device.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view, partially broken, illustrating an enclosure constructed in accordance with the present invention;

FIG. 2 is a perspective view illustrating an underside of the enclosure of the present invention;

FIG. 3 is a cross-sectional view illustrating the enclosure mounted to the circuit board by bolts;

FIG. 4 is a cross-sectional view illustrating the enclosure mounted to the circuit board by bolts in accordance with another embodiment of the present invention;

FIG. 5 is a cross-sectional view illustrating the enclosure mounted to the circuit board by resilient pins; and

FIG. 6 is an exploded view illustrating an application of the enclosure in accordance with the present invention.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

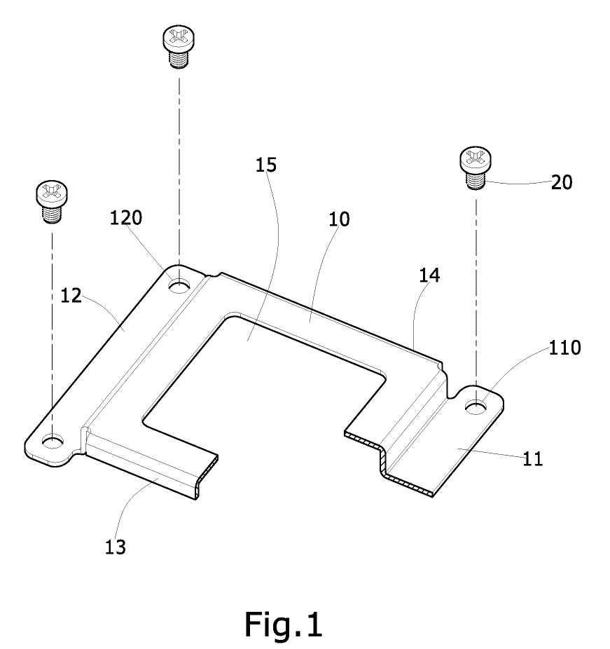

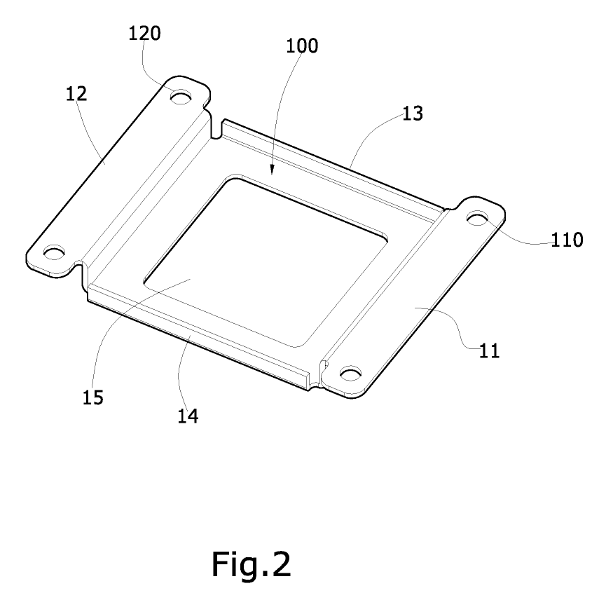

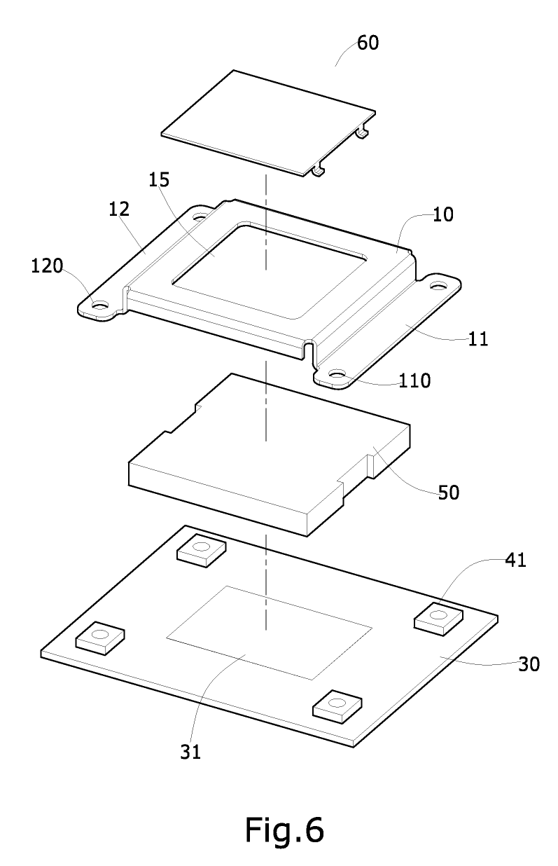

With reference to the drawings and in particular to FIGS. 1 and 2, an enclosure constructed in accordance with the present invention comprises, at a central portion thereof, a frame-like board 10, which forms a central opening 15. The frame-like board 10 has opposite edges, which are bent downward and further extend outward to respectively form parallel side wings 11, 12, in which fastening holes 110, 120 are respectively defined. The frame-like board 10 has two further edges, other than the two that form the side wings 11, 12, and the two further edges are bent downward to form reinforcement flanges 13, 14, whereby the underside of the frame-like board 10, as shown in FIG. 2, forms an accommodation space 100 that are delimited by the two side wings 11, 12 and the two reinforcement flanges 13, 14 for accommodating an electronic device or component 50, which is shown in FIG. 6. The electronic device 50 can be for example an electric connector, especially a socket connector that receives an electronic chip, which is arranged on a preset soldering position 31 on a circuit board 30. However, it is noted that the electric connector is of no concern of the present invention and it is only illustrated schematically for the purposes of brief description only.

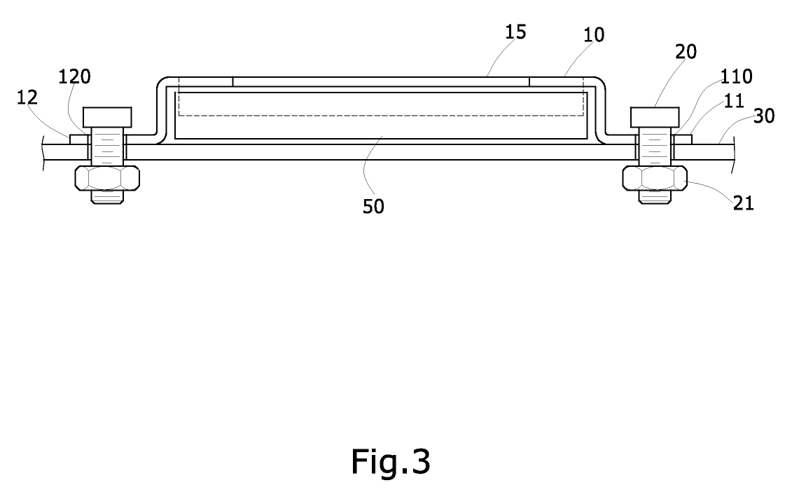

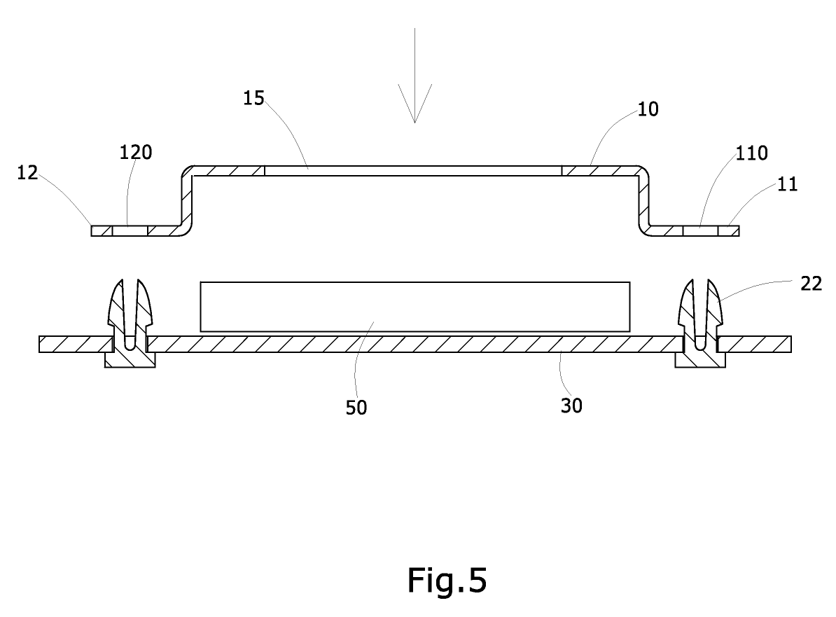

Referring now to FIGS. 1 and 3, the enclosure of the present invention comprises a plurality of fastening elements that are arranged on the side wings 11, 12 in order to fasten the enclosure to the circuit board 30 for neatly and securely fit over and enclose the electronic device 50. The fastening elements can be for example screws/bolts 20, or can alternatively be rivets (not shown), or can even be resilient pins 22 as shown in FIG. 5.

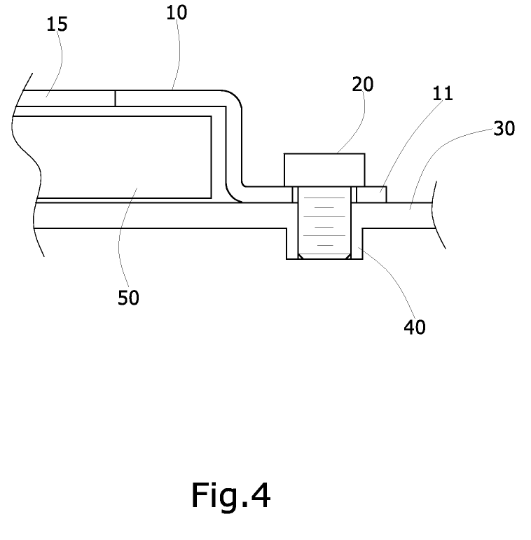

Reference is now made to FIGS. 1, 2, and 3. When the fastening elements are embodied as bolts 20, as shown in FIG. 3, with the frame-like board 10 hoods downward on the electronic device 50, the bolts 20 are fit through the fastening holes 110, 120 of the side wings 11, 12 and further extend through the circuit board 30 to engage nuts 21. It is noted that nuts 21 can be substituted by locking seats 40, 41 shown in FIGS. 4 and 6 respectively The locking seats 40, 41 are directly fit to or fixed on an upper surface (FIG. 6) or a lower surface (FIG. 4) of the circuit board 30 to facilitate threading fastening operation.

Referring to FIG. 5, in case of using the resilient pins 22, the pins are directly fit into the circuit board 30 from an opposite side of the circuit board 30 in a reversed, upward direction to have a barbed end (arrow head) pointing upward. When the frame-like board 10 is depressed downward, the fastening holes 110, 120 of the side wings 11, 12 are fit over and engage the pins 22 for snap-on engagement.

Referring to FIG. 6, the opening 15 of the frame-like board 10 can be further provided with a cap 60, which can be made of plastics in any desired form. The cap 60 can serve as a portion that is attracted by suction force induced by suction cups in assembling a connector. If the cap 60 is removed from the frame-like board 10, the opening 15 of the frame-like board 10 can be used to mount a heat dissipation fan.

In view of the above description, it is apparent that the present invention at least has the following advantages:

(1) The enclosure of the present invention uses a single metal board, which works with fastening elements, to replace the conventional two-layered metal casing structure, which is heavy, so that saving of costs and reduction of weight can be realized, these being the primary benefit offered by the present invention.

(2) The enclosure of the present invention does not bond with the electric connector accommodated therein so that the enclosure of the present invention can be repeatedly usable and is not subjected to the high temperature occurring in bonding the enclosure and the connector. Since the enclosure hooding or fitting over the connector is a low temperature process, components or parts will not be damaged, this being another benefit of the present invention.

(3) The present invention can realize direct and easy mounting to a circuit board by simply using a single metal board that is fastened by bolts or rivets or resilient pins, this being a further advantage of the present invention. To conclude, the present invention provides a unique and novel design, of which the primary feature is using a single metal enclosure, working with fastening elements, to secure an electronic device, such as an electric connector, which remains unchanged even the contour of the metal board that forms the enclosure changes, such being modified as a rectangle or a square, or even the shapes of the side wings are changed, or is additionally provided with for example hinges.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

1. An enclosure of an electronic device comprising:
a centrally located frame-like board, which forms a central opening, the frame-like board having opposite edges, which are bent downward and further extend outward to form parallel side wings, in which four fastening holes are defined, the side wings and the frame-like board together forming an accommodation space on an underside of the frame-like board; and
four fastening elements fit through the side wings of the enclosure and adapted to secure to a circuit board to securely fit on an electronic device.

2. The enclosure as claimed in claim 1, wherein the fastening elements comprise bolts.

3. The enclosure as claimed in claim 1, wherein the fastening elements comprise rivets.

4. The enclosure as claimed in claim 1, wherein the fastening elements are resilient pins.

5. The enclosure as claimed in claim 1, wherein the frame-like board has at least one edge other than the edges that form the side wings, the said at least one edge being bent downward to form a reinforcement flange.

6. The enclosure as claimed in claim 1, wherein the frame-like board has two other edges different from the edges that form the side wings, the said other edges being bent downward to form reinforcement flanges.

7. The enclosure as claimed in claim 1 further comprising a cap mounted on the opening of the frame-like board.

8. The enclosure as claimed in claim 1 further comprising a heat dissipation fan mounted on the opening of the frame-like board.
